(19) United States
(12) Patent Application Publication
(10) Pub. No.: US 2008/0174270 A1
(43) Pub. Date: Jul. 24, 2008

(54) Integrated battery and charger for laptop computer

(76) Inventor: Guillermo Castano De La Serna, Tijuana, CA (US)

Correspondence Address: ROGITZ & ASSOCIATES, 750 B STREET, SUITE 3120, SAN DIEGO, CA, 92101, US

(21) Appl. No.: 11/656,108

(22) Filed: Jan. 22, 2007

(51) Int. Cl. H05K 7/02; H01M 2/02; H02J 7/02

(52) U.S. Cl. 320/111; 361/683; 429/7

(57) ABSTRACT

A battery that slides into a battery bay in a laptop computer is housed integrally with its own power converter and battery charging circuit.

### FIELD OF THE INVENTION

The present invention relates generally to batteries and chargers for laptop computers.

### BACKGROUND OF THE INVENTION

The conveniences afforded by the portability of battery-powered laptop computers can be frustrated in part by the need for the user to carry with him an external battery charger to ensure that the laptop batteries do not run low during, e.g., important meetings or other events. Typically, the battery charger is a brick-like object that has two cords, one for plugging into an AC electrical socket and the other for plugging into the laptop to recharge the battery of the laptop. The present invention recognizes that it can be cumbersome and inconvenient to have to carry this additional device along with the laptop, and furthermore that if the user forgets to bring the charger, the laptop can become inoperable at remote locations in which the user desires to use the laptop. With these critical observations in mind, the invention herein is provided.

### SUMMARY OF THE INVENTION

A portable computer has a screen member holding a computer monitor and a base member bearing an array of computer keys. The base member is hingedly engaged with the screen member for movement between a closed configuration, wherein the screen member and base member are substantially flush against each other with the monitor and array not being exposed to a user, and an open configuration, wherein the screen member is not substantially flush with the base member and the monitor and array are exposed to a user. A battery housing is removably engageable with the base member or screen member. The housing holds a battery and an AC to DC converter such that the converter is internal to the housing. The converter is electrically connected or connectable to a power cord having a first plug configured for engaging an AC power outlet, so that the converter can convert AC power to DC to charge the battery. With this arrangement, no electrical cord external to the housing is required to connect the converter to the battery.

In some implementations the cord has a second plug configured for engaging a socket on the housing. In other implementations the cord has an end opposite the first plug, with the end being disposed in the housing and not being configured for manual removal therefrom by a user.

The housing can be formed from a unitary piece of plastic, and can be slidably engageable with a bay in the base member. If desired, the base member or the screen member can be formed with a cord receptacle such that the cord can be stowed in the receptacle when not in use.

In another aspect, a battery assembly for a computer includes a housing, a battery in the housing, and an AC to DC converter in the housing and electrically connected and/or connectable to the battery. A power cord is connected and/or is connectable to the housing and to an AC power outlet to provide AC power to the converter. Also, an electrical connector is on the housing and is configured for engaging a complementarily-shaped connector on the computer to electrically engage the battery with at least one component in the computer.

In still another aspect, a method is disclosed for providing power to a portable computer. The method includes rigidly engaging a battery with a battery charging power converter, and while the battery is rigidly engaged with the battery charging power converter, sliding the battery into a bay of the portable computer to power the computer. While the battery is in the bay and rigidly engaged with the battery charging power converter, the battery may be charged by electrically connecting the battery charging power converter to an AC outlet.

The details of the present invention, both as to its structure and operation, can best be understood in reference to the accompanying drawings, in which like reference numerals refer to like parts, and in which:

### BRIEF DESCRIPTION OF THE DRAWINGS

FIG. 1 is a perspective view from the rear of a laptop computer in the closed configuration, showing the battery module in an exploded relationship with the laptop; and

FIG. 2 is a perspective view showing the laptop in the open configuration.

### DETAILED DESCRIPTION OF THE PREFERRED EMBODIMENT

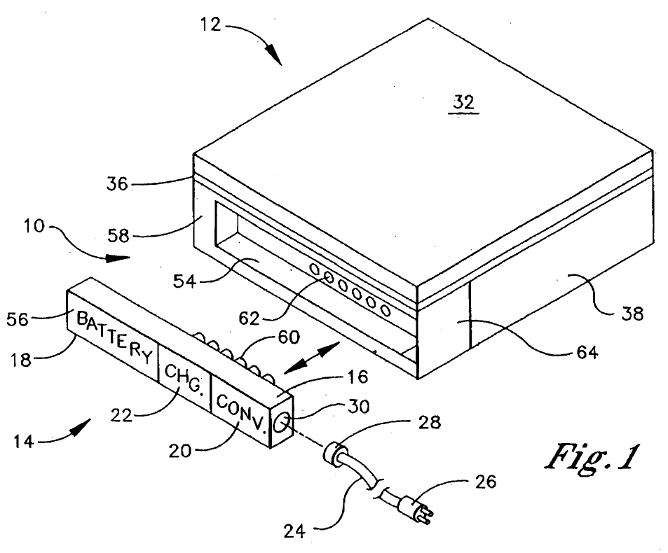

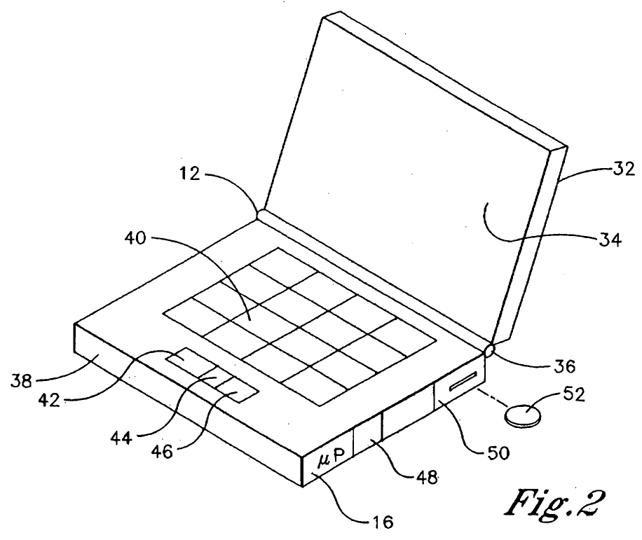

Referring to FIGS. 1 and 2, a system is shown, generally designated 10, that includes a portable computer 12 such as a laptop (sometimes referred to as a “notebook”) computer and an integrated battery module 14. The battery module 14 is integrated in that its below-described constituent parts are rigidly held together and are not configured for separation from each other by a user in the course of using the computer 12 with module 14. Accordingly, in one embodiment the module 14 includes a housing 16 that preferably is made from a unitary piece of molded plastic material and that holds at least one computer battery 18 and at least one AC to DC power converter 20. A battery charging circuit 22 in the housing 16 may interconnect the converter 20 and the battery 18.

The converter 20 can be connected to an AC power outlet by a cord 24. One end of the cord 24 terminates in a plug 26 that is configured for plugging into an AC outlet, while the opposite end of the cord 24 is permanently engaged with the housing 16 and is connected to the converter 20. Or, the cord 24 can be engageable and disengageable with the housing 16 manually by hand by the user by configuring the cord 24 with a battery plug 28 that in turn is configured for engaging a power receptacle 30 in the housing 16 as shown.

FIGS. 1 and 2 show that the computer 12 includes a flat screen member 32 holding a computer monitor 34 that is connected by a hinge 36 to a flat base member 38. The base member 38 bears an array 40 of computer keys as well as a pointing and clicking device such as but not limited to a touch screen 42 and “left” and “right” entry buttons 44, 46.

In accordance with principles known in the art, the screen member 32 can be pivoted against the base member 38 to establish a closed configuration, wherein the screen member 32 and base member 38 are substantially flush against each other as shown in FIG. 1, with the monitor 34 and array 40 not being exposed to a user. Also, the screen member 32 can be pivoted away from the base member 38 to an open configuration, wherein the screen member 32 is not substantially flush with the base member 38 and the monitor 34 and array 40 are exposed to a user. Also in accordance with principles known in the art, the computer 12, e.g., the base member 38, can hold a computer processor 46, a solid state storage 48, and one or more disk drives 50 such as but not limited to internal hard disk drives and optical drives for receiving optical disks 52.

As best shown in FIG. 1, a battery bay 54 is formed in the computer 12, preferably in the base member 38. The battery bay 54 is configured for slidably or pivotably receiving the module 14 therein, preferably with an outer end 56 of the module 14 substantially flush with the rear end 58 of the computer 12 when fully engaged. Less preferably the module 14 is permanently mounted in the bay 54. To electrically connect the battery 18 with, e.g., the computer processor 46, a module connector 60 is formed on the housing 16 of the module 14, and the module connector 60 engages a complementarily-shaped computer connector 62 in the bay 54 of the computer 12, it being understood that the computer connector 62 is electrically connected to internal components of the computer 12 and that the module connector 60 is electrically connected to the battery 18. In one non-limiting implementation, the connectors 60, 62 are wiping-type connectors. Pin-and-socket connectors can also be used.

If desired, the computer 12 may be formed with a cord receptacle, with the cord 24 being stowable in the receptacle when not in use. The receptacle may be covered by a hinged door 64 as shown in FIG. 1.

With the above combination of structure, it may now be appreciated that a user of the system 10 need only engage the battery module 14 with the computer 12 and need not carry an external battery charger along. Instead, the user need only plug the cord 24 into an AC outlet when it is necessary to charge the battery 18. When the battery module 14 is removable from the computer 12, it can be removed by a user and charged during periods when the computer is not in use, although owing to the inventive advantages disclosed herein the battery module 14 need never be removed from the bay 54 to charge the battery, nor is any power converter that is external to the module 14 necessary. Further, no electrical cord that is external to the battery module 14 is required to connect the converter 20 to the battery 18.

While the particular INTEGRATED BATTERY AND CHARGER FOR LAPTOP COMPUTER is herein shown and described in detail, it is to be understood that the subject matter which is encompassed by the present invention is limited only by the claims.

What is claimed is:

1. A portable computer, comprising:
a screen member holding a computer monitor;
a base member bearing at least an array of computer keys, the base member being hingedly engaged with the screen member for movement between a closed configuration, wherein the screen member and base member are substantially flush against each other with the monitor and array not being exposed to a user, and an open configuration, wherein the screen member is not substantially flush with the base member and the monitor and array are exposed to a user; and
a battery housing removably engageable with at least one of the base member or screen member, the housing holding at least one battery and at least one AC to DC converter such that the converter is internal to the housing, the converter being electrically connected or connectable to a power cord having a first plug configured for engaging an AC power outlet, the converter converting AC power to DC to charge the battery, no electrical cord external to the housing being required to connect the converter to the battery.

2. The computer of claim 1, wherein the cord has a second plug configured for engaging a socket on the housing.

3. The computer of claim 1, wherein the cord has an end opposite the first plug, the end being disposed in the housing and not being configured for manual removal therefrom by a user.

4. The computer of claim 1, wherein the housing is formed from a unitary piece of plastic.

5. The computer of claim 1, wherein the housing is slidably engageable with a bay in the base member.

6. The computer of claim 1, wherein the base member or the screen member is formed with a cord receptacle, the cord being stowable in the receptacle when not in use.

7. A battery assembly for a computer, comprising:
a housing;
at least one battery in the housing;
at least one AC to DC converter in the housing and electrically connected and/or connectable to the battery;
at least one power cord connected and/or connectable to the housing and to an AC power outlet to provide AC power to the converter; and
an electrical connector on the housing and configured for engaging a complementarily-shaped connector on the computer to electrically engage the battery with at least one component in the computer.

8. The assembly of claim 7, wherein the housing is unitary.

9. The assembly of claim 8, wherein the housing is made from a single piece of plastic.

10. The assembly of claim 7, wherein the cord has a plug configured for engaging a socket on the housing.

11. The assembly of claim 7, wherein the cord has an end disposed in the housing and not being configured for manual removal therefrom by a user.

12. The assembly claim 7, wherein the housing is configured for slidable engagement with a bay in the computer.

13. A method for providing power to a portable computer, comprising:
rigidly engaging at least one battery with at least one battery charging power converter;
while the battery is rigidly engaged with the battery charging power converter, sliding the battery into a bay of the portable computer to power the computer; and
while the battery is in the bay and rigidly engaged with the battery charging power converter, charging the battery by electrically connecting the battery charging power converter to an AC outlet.

14. The method of claim 13, wherein the act of rigidly engaging the battery with the battery charging power converter includes disposing the battery and the component in an integrated battery module, the module being slidable engageable with the bay of the computer.

15. The method of claim 14, wherein the battery charging power converter includes at least one AC to DC power converter.

16. The method of claim 14, wherein the module is unitary.

17. The method of claim 16, wherein the module is made from a single piece of plastic.

18. The method of claim 14, wherein the module is connected to a cord having a plug configured for engaging a socket on the module.

19. The method of claim 14, wherein the module is connected to a cord having an end disposed in the module and not being configured for manual removal therefrom by a user.
